(19) United States
(12) Patent Application Publication
(10) Pub. No.: US 2025/0255168 A1
(43) Pub. Date: Aug. 7, 2025

(54) CURVED DISPLAY APPARATUS, A LAMINATING APPARATUS AND METHOD THEREOF

(71) Applicant: Samsung Display Co., LTD., Yongin-si (KR)

(72) Inventors: Jung Kyu LEE, Yongin-si (KR); KISANG YOO, Yongin-si (KR)

(73) Assignee: Samsung Display Co., LTD., Yongin-si (KR)

(21) Appl. No.: 18/926,972

(22) Filed: Oct. 25, 2024

(30) Foreign Application Priority Data
Feb. 6, 2024 (KR) 10-2024-0018123

(51) Int. Cl. H10K 71/50; H10K 59/80

(52) U.S. Cl. CPC H10K 71/50; H10K 59/872; H10K 59/8722

(57) ABSTRACT

According to an embodiment of the disclosure, a laminating device for a curved display device that bonds a display panel to a protective cover plate including a flat area and an edge bending area around the flat area with an optical adhesive layer includes a pad portion with the display panel provided on top, a lower jig that supports the pad unit and is configured to move up and down perpendicular to the upper jig, and an independently controlled heating unit installed on the pad portion, that selectively or independently controls the temperature of the optical adhesive layer on at least a portion of the protective cover plate during bonding of the protective cover plate and the display panel to eliminate unpredictability in edge bending areas of the protective cover plate.

### CROSS-REFERENCE TO RELATED APPLICATION(S)

This application claims priority to and benefits of Korean Patent Application No. 10-2024-0018123 under 35 U.S.C. § 119, filed at the Korean Intellectual Property Office on Feb. 6, 2024, the entire contents of which are incorporated herein by reference.

### BACKGROUND

### (1) Technical Field

The disclosure relates to a curved display device with high curvature that can solve expected defects, and a laminating device and method thereof.

### (2) Description of the Related Art

Display devices include liquid crystal displays (LCDs) and organic light emitting displays (OLEDs).

A liquid crystal display (LCD) includes a liquid crystal display panel that displays an image using light transmittance of liquid crystals, and a backlight assembly disposed below the liquid crystal display panel to provide light to the liquid crystal display panel.

An organic light emitting display OLED displays images using organic light emitting diodes (OLEDs) that emit light by recombination of electrons and holes.

Organic light emitting display devices are most widely used because they have a fast response speed and are driven with low power consumption.

In order to provide a wide field of view of the display device, a curved display device in which the edge of the screen is curved toward the viewer is being developed.

A curved display device allows images to be viewed at a wider angle and with an improved sense of depth.

Curved display devices are being developed in various sizes, curvatures, and resolutions suitable for various fields such as TVs, monitors, smart phones, and wearables.

A curved display device may be formed in various structures.

A curved display device may include a protective cover plate that protects the inside from external shocks, and various film members attached to the window.

As a curved display device is often formed in various shapes as described above, accurately attaching the film member to the protective cover plate is an issue.

In particular, various types of devices are being developed to accurately attach the film member to the protective cover plate, and various research is also being conducted.

It is to be understood that this background of the technology section is, in part, intended to provide useful background for understanding the technology.

However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure was created to solve these problems, and an aspect of the disclosure is to provide a high-curvature curved display device, and a laminating device and method thereof, that can solve expected defects that may occur in the curved area of the curved display device.

According to an embodiment of the disclosure, a laminating device for a curved display device that bonds a display panel to a protective cover plate including a flat area and an edge bending area around the flat area with an optical adhesive layer. The laminating device for the curved display device may include a pad portion with the display panel provided on top, a lower jig that supports the pad portion and is configured to move up and down perpendicular to the upper jig, and an independently controlled heating unit installed on the pad portion to selectively or independently control the temperature of the optical adhesive layer for at least a portion of the protective cover plate while bonding the protective cover plate and the display panel to eliminate unpredictability in edge bending areas of the protective cover plate.

A laminating device for the curved display device according to one embodiment may further include an upper jig including a fixing part that fixes the protective cover plate by vacuum suction, and a moving part that moves the protective cover plate fixed by the fixing part. The lower jig may include a base plate supporting the support body of the pad portion, and a vertical driving part that vertically drives the pad portion.

According to a laminating device for the curved display device according to one embodiment, the pad portion may include a curved elastic pad part on which the display panel is disposed and whose upper surface changes to correspond to the curved shape of the protective cover plate in case that the upper jig or the lower jig moves in a vertical direction, and a support body configured to be detachable from the curved elastic pad part. The independently controlled heating member may be selectively installed with respect to the curved elastic pad part.

According to a laminating device for the curved display device according to one embodiment, a carrier film supply unit may supply a carrier film to which the display panel is attached is installed offset with respect to the pad portion.

A laminating device for the curved display device according to one embodiment may further include a control device that independently controls the power and temperature of the independently controlled heating member so that the curved elastic pad part of the pad portion can self-generate.

A laminating device for the curved display device according to one embodiment may further include a temperature sensor installed for each of the independently controlled heating members, and a control device that communicates with the temperature sensor to independently control power on/off and temperature of the independently controlled heating member.

A laminating device for the curved display device according to one embodiment may further include a cooling device that locally and quickly cools the independently controlled heating member in conjunction with the control device.

According to a laminating device for the curved display device according to one embodiment, the independently controlled heating member may be a laminating device for the curved display device, and the independently controlled heating member may be at least one of a metal sheet, a metal tube, a metal block, and a metal wire.

According to a laminating device for the curved display device according to one embodiment, the independently controlled heating member may be disposed in the central area of the curved elastic pad part corresponding to the flat area of the protective cover substrate, and the central area of the curved elastic pad part may be surrounded by a protruding support portion protruding upward from the support body.

According to a laminating device for the curved display device according to one embodiment, the independently controlled heating member may be disposed in a corner area of the curved elastic pad part corresponding to the edge bending area of the protective cover substrate, and the corner area may be a curved display formed outside the protruding support portion protruding upward from the support body.

According to a laminating device for the curved display device according to one embodiment, the optical adhesive layer may be made of an acrylic optical adhesive, may have low high-temperature adhesive strength compared to room-temperature adhesive strength, and modulus and cohesion may decrease as the temperature increases.

According to a laminating device for the curved display device according to one embodiment, the independently controlled heating member may include a first metal heating wire that is independently and discretely disposed with respect to the curved elastic pad part, and a second metal heating wire in the form of a mesh that intersects in the x-axis direction and the y-axis direction. The independently controlled heating member may have controllable spacing in the x-axis direction and y-axis direction and can be sewn to the curved elastic pad part. The independently controlled heating member may include a third metal heating wire in the form of a closed curve that is independently and discretely disposed with respect to the curved elastic pad part, and a fourth metal heating wire that is independently disposed and independently controlled with respect to a corner area of the curved elastic pad part.

A laminating method for a curved display device according to an embodiment of the disclosure may include providing a protective cover plate including a middle flat area and an edge bending area around the flat area using an upper jig, providing a pad portion disposed below the upper jig using a lower jig, providing a display panel having an optical adhesive layer on the pad portion, moving the upper jig or the lower jig in directions perpendicular to each other to bond the protective cover plate below the upper jig and the display panel on the pad portion disposed on the lower jig through the optical adhesive layer, and eliminating unpredictability occurring in an edge bending area of the protective cover plate by selectively or independently controlling the temperature of the optical adhesive layer for at least a portion of the protective cover plate.

The laminating method for a curved display device according to one embodiment of the disclosure may include removing wrinkles by heating a central area of the display panel corresponding to the flat area of the protective cover plate, and increasing fluidity by indirectly heating the optical adhesive layer placed on the central area of the display panel.

A laminating method for a curved display device according to an embodiment of the disclosure may include forming a curved area by heating an edge area of the display panel corresponding to an edge bending area of the protective cover plate

A laminating method for a curved display device according to an embodiment of the disclosure may include heating the edge area of the display panel to lower the adhesive strength compared to room temperature by heating the optical adhesive layer disposed on the edge area of the display panel to a high temperature above room temperature, and removing air bubbles through the edge area of the corresponding display panel.

A laminating method for a curved display device according to another aspect of the disclosure may include selectively or independently controlling the temperature of the optical adhesive layer on the display panel for at least a portion of the protective cover plate by moving the upper jig and the lower jig in a direction perpendicular to each other while joining the curved protective cover plate below the upper jig and the display panel on the lower jig to eliminate unpredictability in the edge bending area of the protective cover plate. The temperature of the optical adhesive layer may be controlled through an independent controllable heating member included in the pad portion on which the display is disposed, and the independently controllable heating member may be embedded in the entire area or partial area of the pad portion. The independently controlled heating member may be a metal sheet, metal tube, or metal block selectively disposed in the central area or edge area of the pad portion, a mesh-shaped metal heating wire intersecting the x-axis direction and the y-axis direction, or has a discrete closed curve shaped.

A laminating method for a curved display device according to an embodiment of the disclosure may include a plurality of independently controlled heating members disposed separately, each being controlled on and off according to a temperature measurement value measured by a temperature sensor disposed on each, wherein the temperature is variable.

A curved display device according to another aspect of the disclosure may include a display panel and a protective cover plate including a flat area and an edge bending area around the flat area with an optical adhesive layer. The display panel and the protective cover plate may be bonded to each other. Unpredictability in the edge bending area may be eliminated by selectively or independently controlling a temperature of the optical adhesive layer for at least a portion of the protective cover plate while bonding the protective cover plate and the display panel.

A curved display device according to an embodiment of the disclosure may include a predicted amount being a bonding defect that occurs in case that the optical adhesive layer makes line contact with the edge bending area of the protective cover plate. The bonding defect may be caused by chafing, bending, or stress accumulation of an optical adhesive forming the optical adhesive layer, through at least one of buckling, film delamination, and bubbling.

According to the curved display device, and its laminating device and method according to an embodiment of the disclosure, the pad unit on which the display panel is disposed may be configured to be separated into a curved elastic pad part and a support body, and the curved elastic pad part may be provided with a support body, where independently controlled heating members can be selectively installed in various materials, shapes, and designs, and can be readily replaced, where the support body evenly supports the curved elastic pad at the bottom in case that the protective cover plate is pressed by the upper jig.

According to the curved display device, in its laminating device and method according to an embodiment of the disclosure, an independently controlled heating member may be disposed in the central area of the display panel to provide an ironing effect to prevent wrinkles from forming on the display panel. By improving the fluidity of the optical adhesive layer, the edge bending area of the protective cover plate can be evenly filled.

According to the curved display device, in its laminating device and method according to an embodiment of the disclosure, an independently controlled heating member may be disposed at the edge area of the display panel and may be bonded to at least a portion of the edge bending area of the protective cover plate, the edge area may avoid line contact and make surface contact so that the inner surface of the optical adhesive layer can be well filled, and the possibility of air bubbles existing between the optical adhesive layer and the edge bending area after bonding can be effectively reduced.

According to the curved display device, in its laminating device and method according to an embodiment of the disclosure, in case that the independently controlled heating member is independently arranged with a metal heating wire or a metal heating sheet, the pad unit may have a small volume and a small occupied space, so the curved elastic pad may be readily placed on a curved surface, and the curved elastic pad can be attached and detached, so the structural design of the curved elastic pad can be changed in various ways without affecting the overall structural design of the pad unit.

### BRIEF DESCRIPTION OF THE DRAWINGS

FIG. 1 is a schematic cross-sectional view of a portion of a display device according to an embodiment of the disclosure.

FIG. 2 is a schematic cross-sectional view showing the display panel shown in FIG. 1.

FIG. 3 is a schematic view of a laminating device for a display device according to an embodiment of the disclosure.

FIG. 4 is a schematic cross-sectional view of FIG. 3.

FIG. 5 is a schematic diagram showing the CAE analysis results during the high curvature laminating of FIG. 4.

FIG. 6 to FIG. 8 are schematic graphs showing room temperature adhesive strength, high temperature adhesive strength, and modulus and cohesion according to temperature in case using an acrylic optical adhesive.

FIG. 9 is a schematic perspective view of a laminating device for a display device according to another embodiment of the disclosure.

FIGS. 10 to 12 and FIGS. 13A and 13B are schematic diagrams of pad units according to first to fourth modifications of other embodiments of the disclosure.

FIG. 14 is a schematic configuration diagram of a control device for a laminating device for a display device according to another embodiment of the disclosure.

FIG. 15 is a schematic flowchart showing a control method of a laminating device for a display device according to another embodiment of the disclosure.

FIG. 16 is a schematic flowchart showing the expected defect control method of FIG. 15.

### DETAILED DESCRIPTION OF THE EMBODIMENTS

Since the disclosure can be modified in various ways and can have various embodiments, only a limited number of specific embodiments will be illustrated in the drawings and described in detail in the detailed description.

The effects and features of the disclosure and methods for achieving them will become clear by referring to the embodiments described in detail below along with the drawings.

However, the disclosure is not limited to the embodiments disclosed below and may be implemented in various forms.

In the following embodiments, terms such as first and second are used not in a limiting sense but for the purpose of distinguishing one component from another component.

Singular expressions include plural expressions unless the context clearly dictates otherwise.

Terms such as include or have mean that the features or components described in the specification exist, and do not preclude the possibility of adding one or more other features or components.

In the drawings, the sizes of components may be exaggerated or reduced for convenience of explanation.

For example, the size and thickness of each component shown in the drawings may be arbitrarily shown for convenience of explanation, and the disclosure is not necessarily limited to that which is shown.

In the following embodiments, the x-axis, y-axis, and z-axis are not limited to the three axes in the Cartesian coordinate system, but may be interpreted in a broad sense including these.

For example, the x-axis, y-axis, and z-axis may be orthogonal to each other, but may also refer to different directions that are not orthogonal to each other.

In cases where an embodiment can be implemented differently, a specific process sequence may be performed differently from the described sequence.

For example, two processes described in succession may be performed substantially at the same time, or may be performed in an order opposite to that in which they are described.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described in detail with reference to the accompanying drawings. When describing with reference to the drawings, identical or corresponding components will be assigned the same reference numerals and redundant description thereof will be omitted.

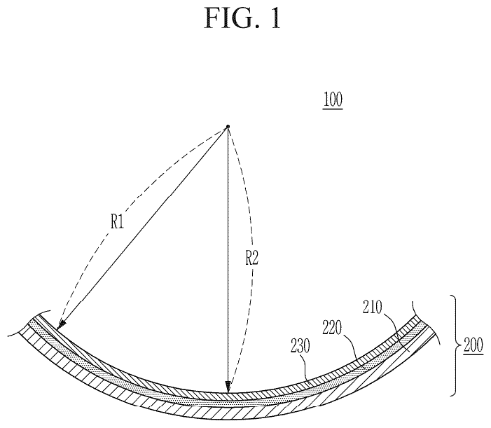

FIG. 1 is a schematic cross-sectional view showing a portion of a display device manufactured using a lamination device according to an embodiment of the disclosure.

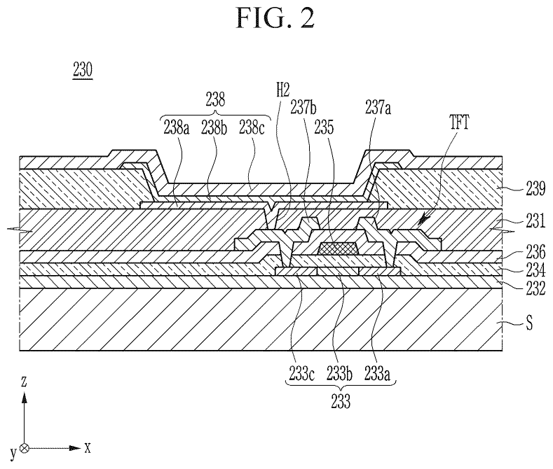

FIG. 2 is a schematic cross-sectional view showing the display panel shown in FIG. 1.

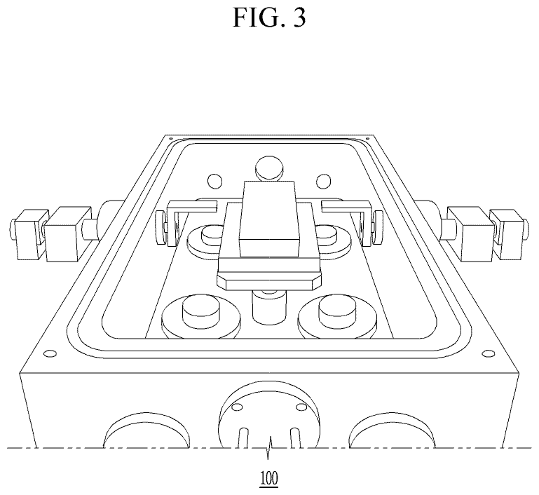

The display device 200 shown in FIGS. 1 and 2 can be manufactured using the laminating device 100 according to an embodiment of the disclosure shown in FIG. 3.

As shown in FIGS. 1 and 2, the display device 200 may include a protective cover plate 210 and a film member (not shown).

The protective cover plate 210 may be formed as a curved surface having multiple radii of curvature.

For example, the protective cover plate 210 can be formed with a first curved surface having a first curvature radius R1 in the length direction or width direction, and a second curved surface having a second curvature radius R2.

The protective cover plate 210 may further include curved surfaces having different radii of curvature in addition to the curved surfaces having a radius of curvature of R1 to R2.

The protective cover plate 210 may be formed as a curved surface with a constant radius of curvature.

For example, the protective cover plate 210 may be formed as a curved surface with a constant radius of curvature.

The protective cover plate 210 may have a curved area having a radius of curvature and a flat area formed to be flat.

Hereinafter, for convenience of explanation, the description will focus on the case where the protective cover plate 210 is formed as a curved surface with a constant radius of curvature at both ends.

The film member can be formed in various ways.

For example, the film member can include at least one of the touch screen panel (not shown), a display panel 230, an optically clear adhesive film OCA 220, a black matrix film (not shown), and a release paper (not shown).

Since the touch screen panel may be the same or similar to a general touch screen panel, redundant description will be omitted.

The display panel 230 may include a flexible organic light emitting display panel, a liquid crystal display panel, etc.

The optical adhesive layer 220 may be disposed between the display panel 230 and the protective cover plate 210, and may be attached by the lamination device 100 before attaching the display panel 230.

The optical adhesive layer 220 may be manufactured by being attached to the protective cover plate 210 or the display panel 230.

The black matrix film may have a black matrix printed on an adhesive film.

The release paper may be a film that is attached to the protective cover plate 210 and protects the protective cover plate 210.

The film member may be formed to be flexible.

For convenience of explanation, the following will focus on the case where the lamination device 100 presses the protective cover plate 210 and attaches it to the display panel 230 made of a flexible film member through the optical adhesive layer 220.

In particular, a detailed description will be given focusing on the case where the display panel 230 is an organic light emitting display panel.

As described above, the display panel 230 made of a flexible film member may be attached to the convex or concave surface of the protective cover plate 210.

Hereinafter, for convenience of explanation, a detailed description will be given focusing on the case where the display panel 230 made of the flexible film member is attached to the concave surface of the protective cover plate 210.

The display panel 230 may have the light emitting portion formed on a first substrate S.

The light emitting unit may be equipped with a thin film transistor TFT, a passivation layer 231 may be formed to cover the TFT, and an organic light emitting device 238 can be formed on the passivation layer 231.

The first substrate S may be made of glass, but is not necessarily limited to this, plastic materials may be used, and metal materials such as stainless-steel SUS or titanium Ti may also be used.

The first substrate S may be made of a polyimide (PI).

Hereinafter, for convenience of explanation, a detailed description will be given focusing on the case where the first substrate S is formed of a polyimide.

A buffer layer 232 made of an organic compound and/or an inorganic compound may further be formed on the upper surface of the first substrate S, and may be formed of SiOₓ (x≥1) or SiNₓ (x≥1).

After the active layer 233 arranged in a predetermined pattern is formed on the buffer layer 232, the active layer 233 may be buried by the gate insulating layer 234.

The active layer 233 may have a source region 233a and a drain region 233c, and may further include a channel region 233b between the source region 233a and the drain region 233c.

This active layer 233 may be formed to contain various materials.

For example, the active layer 233 may contain an inorganic semiconductor material such as amorphous silicon or crystalline silicon.

As another example, the active layer 233 may contain an oxide semiconductor.

As another example, the active layer 233 may contain an organic semiconductor material.

However, for convenience of explanation, hereinafter, the detailed description will focus on a case where the active layer 233 is formed of amorphous silicon.

The active layer 233 can be formed by forming an amorphous silicon film on the buffer layer 232, crystallizing it to form a polycrystalline silicon film, and patterning the polycrystalline silicon film.

The source region 233a and drain region 233c of the active layer 233 are doped with impurities depending on the type of TFT, such as a driving TFT (not shown) or a switching TFT (not shown).

A gate electrode 235 corresponding to the active layer 233 and an interlayer insulating layer 236 burying the active layer 233 may be formed on the upper surface of the gate insulating layer 234.

After forming contact holes in the interlayer insulating layer 236 and the gate insulating layer 234, the source electrode 237a and the drain electrode 237b may be formed on the interlayer insulating layer 236 in the source region 233a and the drain electrode 237b, respectively, and may be formed to contact the drain region 233c.

A passivation layer 231 may be formed on the top of the thin film transistor formed in this way, and the pixel electrode 238a of the organic light emitting device OLED is formed on the passivation layer 231.

This pixel electrode 238a may be contacted to the drain electrode 237b of the TFT by a via hole H2 formed in the passivation layer 231.

The passivation layer 231 can be formed of inorganic and/or organic materials, in a single layer or two or more than two layers, and it can be formed as a flattening film so that the upper surface becomes flat regardless of the curvature of the lower film, and on the other hand, it can be formed to have a curvature following the curvature of the film located below.

The passivation layer 231 may be formed of a transparent insulator to achieve a resonance effect.

After forming the pixel electrode 238a on the passivation layer 231, a pixel defining film 239 may be formed of an organic material and/or an inorganic material to cover the pixel electrode 238a and the passivation layer 231, and may be opened to expose the pixel electrode 238a.

An intermediate layer 238b and an opposing electrode 238c may be formed on at least the pixel electrode 238a.

The pixel electrode 238a functions as an anode electrode, and the counter electrode 238c may function as a cathode electrode, and of course, the polarities of the pixel electrode 238a and the counter electrode 238c may be reversed.

The pixel electrode 238a and the counter electrode 238c may be insulated from each other by the middle layer 238b, and voltages of different polarities may be applied to the middle layer 238b to cause light emission from the organic light emitting layer.

The middle layer 238b may include an organic light emitting layer.

As another optional example, the intermediate layer 238b may include an organic emission layer and, in addition, a hole injection layer (HIL), a hole transport layer, and an electron transport layer and at least one of an electron injection layer may be further provided.

Embodiments are not limited to this configuration, and the middle layer 238b may include an organic light emitting layer and may further include various other functional layers.

A unit pixel may be made up of subpixels, and the subpixels can emit light of various colors.

For example, the subpixels may include subpixels that emit red, green, and blue light, respectively, and may include subpixels that emit red, green, blue, and white light.

Each of the subpixels as described above may be provided with an intermediate layer 238b including an organic light emitting layer that emits light of various colors.

For example, the subpixels may each include an intermediate layer 238b including an organic light emitting layer that emits red, green, and blue light.

As another example, subpixels emitting various colors may include an intermediate layer 238b including an organic light emitting layer that emits light of the same color, for example, white, and converts the white light into light of a predetermined color, and it may include a color converting layer or a color filter.

The middle layer 238b emitting white light may have various structures. For example, the middle layer 238b may include at least a light emitting material emitting red light, a light emitting material emitting green light, and a light emitting material emitting blue light, and it may include a layered structure of materials.

As another example for emitting the white light, the intermediate layer 238b may include a mixed structure of at least a light emitting material that emits red light, a light emitting material that emits green light, and a light emitting material that emits blue light.

The colors red, green, and blue are examples, and embodiments are not limited thereto.

If white light can be emitted, combinations of various colors other than red, green, and blue can be used.

The display panel 230 may further include a thin film encapsulation layer, and the thin film encapsulation layer may include multiple inorganic layers or may include an inorganic layer and an organic layer.

The organic layer of the thin film encapsulation layer may be formed of a polymer, and may be a single film or a laminated film formed of any one or more of polyethylene terephthalate, polyimide, polycarbonate, epoxy, polyethylene, and polyacrylate.

In an embodiment, the organic layer may be formed of polyacrylate, and specifically, may include a polymerized monomer composition containing a diacrylate-based monomer and a triacrylate-based monomer.

The monomer composition may further include a monoacrylate-based monomer.

The monomer composition may further include a photo initiator such as TPO, but is not limited thereto.

The inorganic layer of the thin film encapsulation layer may be a single film or a stacked film containing a metal oxide or a metal nitride.

Specifically, the inorganic layer may include at least one of SiNₓ, Al₂O₃, SiO₂, and TiO₂.

The top layer exposed to the outside of the thin film encapsulation layer may be formed as an inorganic layer to prevent moisture penetration into the organic light emitting device.

The thin film encapsulation layer may include at least one sandwich structure in which at least one organic layer is inserted between at least two inorganic layers.

As another example, the thin film encapsulation layer may include at least one sandwich structure in which at least one inorganic layer is inserted between at least two organic layers.

As another example, the thin film encapsulation layer may include a sandwich structure in which at least one organic layer is inserted between at least two inorganic layers and a sandwich structure in which at least one inorganic layer is inserted between at least two organic layers.

The thin film encapsulation layer may sequentially include a first inorganic layer, a first organic layer, and a second inorganic layer from the top of the organic light emitting device OLED.

As another example, the thin film encapsulation layer may sequentially include a first inorganic layer, a first organic layer, a second inorganic layer, a second organic layer, and a third inorganic layer from the top of the organic light emitting device OLED.

As another example, the thin film encapsulation layer may sequentially include a first inorganic layer, a first organic layer, a second inorganic layer, the second organic layer, a third inorganic layer, a third organic layer, and a fourth inorganic layer from the top of the organic light emitting device OLED.

A metal halide layer containing LiF may be additionally included between the organic light emitting device OLED and the first inorganic layer.

The halogenated metal layer can prevent the organic light emitting device OLED from being damaged in case that the first inorganic layer is formed by sputtering.

The first organic layer may have a smaller area than the second inorganic layer, and the second organic layer may also have a smaller area than the third inorganic layer.

As another example, the first organic layer can be formed to be completely covered by the second inorganic layer, and the second organic layer can also be formed to be completely covered by the third inorganic layer.

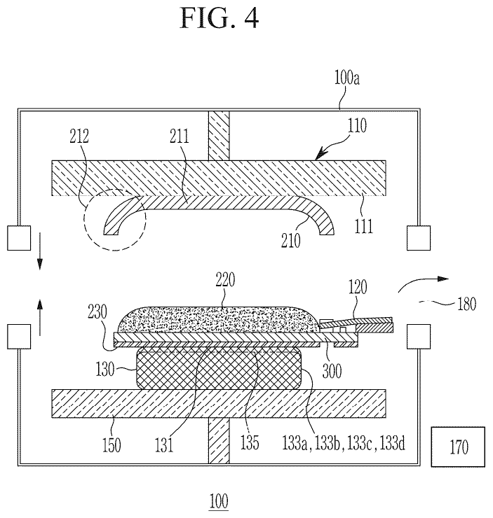

FIG. 3 is a schematic view of a laminating device for a display device according to an embodiment of the disclosure, and FIG. 4 is a schematic cross-sectional view of a laminating device for a display device according to an embodiment of the disclosure.

Referring to FIG. 3 and FIG. 4, the curved surface laminating device 100 for a display device according to an embodiment of the disclosure may include an upper jig 110, a pad unit (portion) 130, and a lower jig 150 disposed in a vacuum chamber 100a.

The upper jig 110 may include a fixing part 111 for fixing the protective cover plate 210 by vacuum adsorption, and the fixing part 111 includes pores and is connected to the vacuum pump to cover the protective cover plate 210 so it can be vacuum adsorbed.

The pad unit 130 may include a curved elastic pad part 131.

The curved elastic pad part 131 may be installed toward the fixing portion 111.

The curved elastic pad part 131 may be disposed to support the display panel 230 having the optical adhesive layer 220.

The upper jig 110 and the pad unit 130 may be arranged to bond the display panel 230 and the protective cover plate 210 via the optical adhesive layer 220.

The pad unit 130 may be placed on the lower jig 150.

The pad unit 130 may include a curved elastic pad part 131 and first to fourth pad sides 133a, 133b, 133c, and 133d that are bent and extended from the curved elastic pad part 131.

The shape of the pad unit 130 can be readily deformed to correspond to the curved shape of the protective cover plate 210 in case that the upper jig 110 and the lower jig 150 move vertically and combine under pressure.

The curved elastic pad part 131 of the pad unit 130 may have a convex shape in the direction from the lower jig 150 to the upper jig 110.

The material of the pad unit 130 is not limited to any one material as long as the shape can be readily modified and restored.

The lower jig 150 may be disposed below the upper jig 110 to support the pad unit 130.

The lower jig 150 can move the pad unit 130 toward the upper jig 110 or move it away from the upper jig 110.

The lower jig 150 and the pad unit 130 can be moved in the left and right directions.

Since a carrier film supply unit 120 for supplying the carrier film 300 with the display panel 230 attached on the pad unit 130 is provided between the lower jig 150 and the upper jig 110, it may be included to be offset relative to the pad unit 130.

The carrier film supply unit 120 may be moved in a direction closer to or away from the pad unit 130.

To this end, the carrier film supply unit 120 is further provided with a roller so that the carrier film 300 can be wound or unwound around the roller while being moved in a direction toward or away from the pad unit 130.

However, embodiments are not limited to this configuration, and the roller may be omitted.

A heating unit 135 may be installed below the curved elastic pad part 131 of the pad unit 130, and since the heating unit 135 is the curved elastic pad part 131 of the pad unit 130 itself, it may be installed on at least a portion of the flat area 211 and the edge bending area 212 of the protective cover plate 210 to generate heat.

The protective cover plate 210 and the display panel 230 may be brought close to each other by moving the lower jig 150 upwards or moving the upper jig 110 downwards, so that the protective cover plate 210 and the display panel 230 can be joined, and during the joining process, the optical adhesive layer 220 can be heated using the curved elastic pad part 131 of the pad unit 130 with the heating unit 135, to enhance the fluidity of the optical adhesive layer 220 for adhesion.

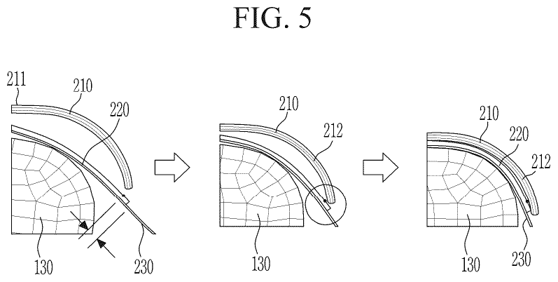

FIG. 5 is a schematic diagram showing the CAE analysis results during the high curvature laminating of FIG. 4.

CAE (Computer-Aided Engineering) shows the results of confirming the fatigue durability between the protective cover plate 210 and the display panel 230 using a computer.

As shown in FIG. 5, in case that the protective cover plate 210 is bonded to the display panel 230 using the optical adhesive layer 220, the optical adhesive layer 220 is attached to the protective cover plate 210, it can be seen that line contact occurs in the edge bending area 212, and poor bonding problems such as optical adhesive chafing, bending or stress collection (buckling), film delamination, and bubble phenomenon occur.

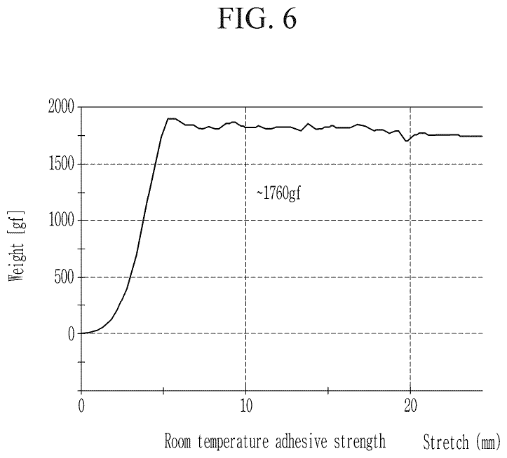

FIGS. 6 to 8 are schematic graphs showing room temperature adhesive strength, high temperature adhesive strength, and modulus and cohesion according to temperature in case that the optical adhesive layer uses an acrylic optical adhesive.

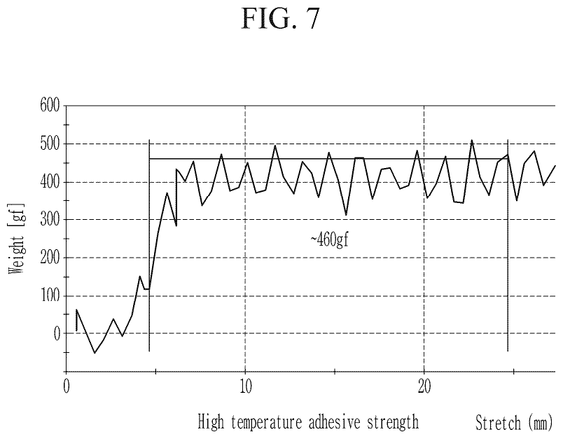

As shown in FIGS. 6 and 7, in case that the protective cover plate 210 is bonded to the display panel 230 using the optical adhesive layer 220, the optical adhesive layer 220 may be a transparent acrylic optical adhesive, and the acrylic optical adhesive may require a load of about 1760 gf to stretch about 10 mm to about 20 mm at room temperature, while a load of about 460 gf may be needed to stretch about 10 mm to about 20 mm at high temperature.

In case that an acrylic-based optical adhesive is used as the optical adhesive layer 220, it can be seen that the high-temperature adhesive strength may be low compared to the room-temperature adhesive strength.

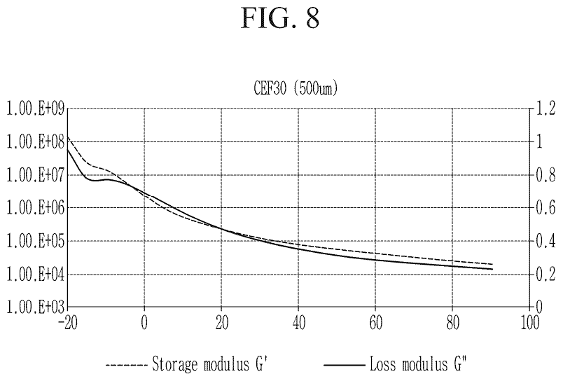

As shown in FIG. 8, in case that an acrylic optical adhesive is used as the optical adhesive layer 220, the storage modulus G′ and loss modulus G″ of the optical adhesive layer 220 are measured with respect to temperature, and as a result, the temperature may decrease as the temperature increases, since both the storage modulus and loss modulus may be lowered, it can be seen that the modulus may be lowered and the cohesion is reduced.

In case bonding the protective cover plate 210 to the display panel 230 using the optical adhesive layer 220 according to the temperature according to the material and physical properties of the optical adhesive layer 220, the pad unit 130, it may be desirable to selectively or independently control the temperature of the curved elastic pad part 131.

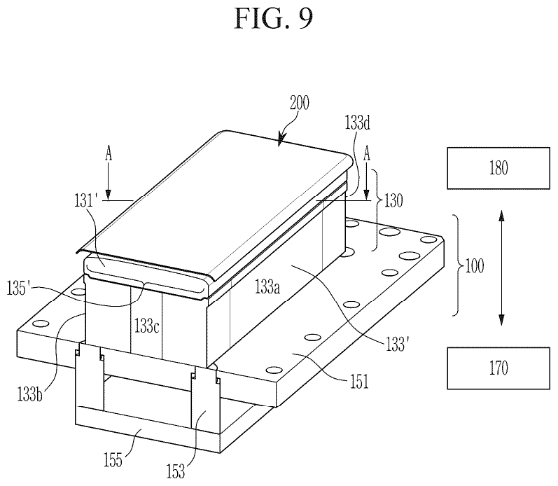

A laminating device and method for a display device according to another embodiment of the disclosure will be described with reference to FIGS. 9 to 15.

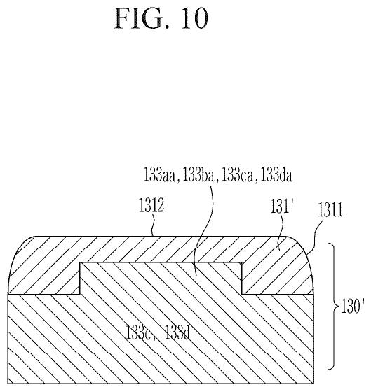

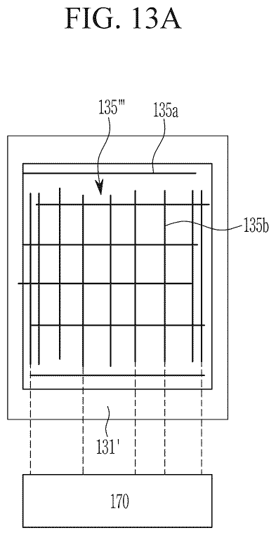

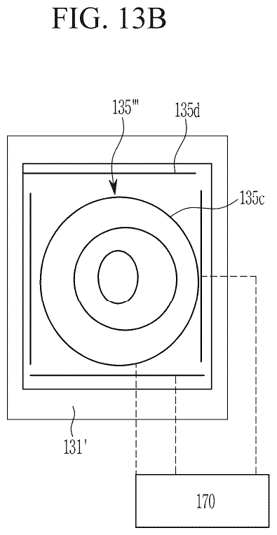

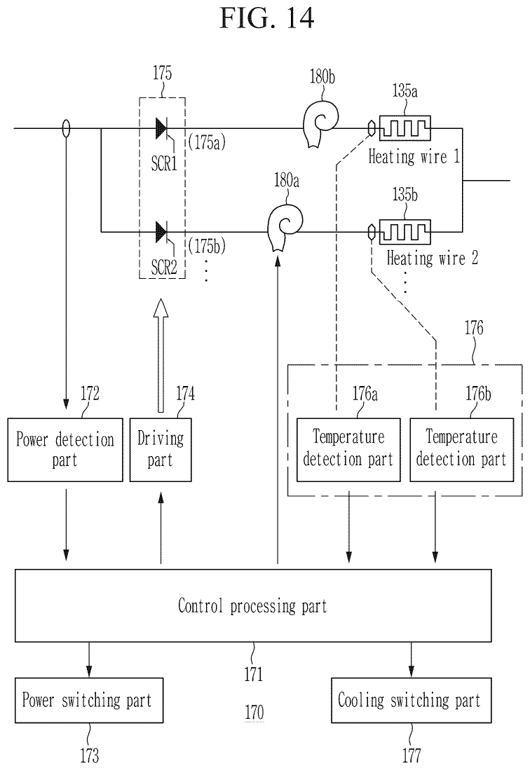

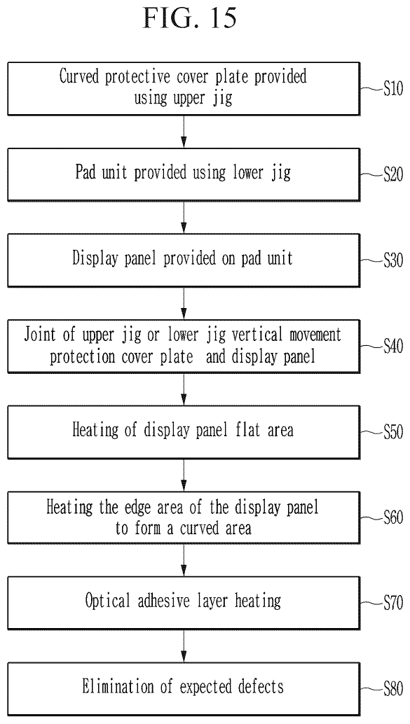

FIG. 9 is a schematic perspective view of the main part of a laminating device for a display device according to another embodiment of the disclosure, FIGS. 10 to 12 are schematic sectional views taken along line A-A of FIG. 9, respectively, FIGS. 13A and 13B are schematic plan views of FIG. 9, FIG. 14 is a configuration diagram of a control device for a laminating device for a display device according to another embodiment of the disclosure, and FIG. 15 is a schematic flowchart showing a control method for a laminating device for a display device according to another embodiment of the disclosure.

First, referring to FIG. 9, the laminating device 100′ for a display device according to another embodiment of the disclosure may be installed in the vacuum chamber 100a like the laminating device 100′ for a display device according to an embodiment of the disclosure, and it may include an upper jig 110, a pad unit 130, and a lower jig 150.

Like the laminating device 100 for a display device according to an embodiment of the disclosure, the upper jig 110 may include a fixing part 111 for fixing the protective cover plate 210 by vacuum adsorption, and the fixing part 111 may include pores and may be connected to a vacuum pump to vacuum adsorb the protective cover plate 210.

In another embodiment of the disclosure, a laminating device 100′ for a display device can place a pad unit 130′ on a lower jig 150′, and the pad unit 130′ may include a curved elastic pad part 131′, a support body 133′ that can be detachably configured for the curved elastic pad part 131′, and an independent control type heating unit 135′ that can be optionally installed for the curved elastic pad part 131′.

Since the pad unit 130′ is configured so that the curved elastic pad part 131′ and the support body 133′ are separated, the independently controlled heating unit 135′ connected to the curved elastic pad part 131′ can be selectively installed and readily replaced, and the support body 133′ is connected to the curved elastic pad at the bottom in case that the protective cover plate 210 is pressed by the upper jig 110, so the portion 131′ can be supported so that it is uniformly pressed toward the top.

The support body 133′ may include first to fourth pad sides 133a, 133b, 133c, and 133d that are bent downward and extend from the curved elastic pad part 131′.

The first to fourth pad sides 133a, 133b, 133c, and 133d may be composed of first and second pad sides 133a and 133b and third and fourth sides 133c and 133d facing each other. In general, the first and second pad sides 133a and 133b may have long sides, and the third and fourth pad sides 133c and 133d may have short sides.

The shape of the curved elastic pad part 131 can be readily deformed to correspond to the curved shape of the protective cover plate 210 in case that the upper jig 110 and the lower jig 150 move in the vertical direction and are pressurized against each other.

The shape of the curved elastic pad part 131 can be readily deformed to correspond to the curved shape of the protective cover plate 210 in case that the upper jig 110 and the lower jig 150 move in the vertical direction and are pressurized against each other.

The curved elastic pad part 131 may have a convex shape in the direction from the lower jig 150 to the upper jig 110.

The material of the curved elastic pad part 131 is not limited to any one material as long as the shape can be readily deformed and restored.

The lower jig 150 may be disposed below the upper jig 110 to support the pad unit 130.

The lower jig 150 may include a base plate 151 on which the support body 133 of the pad unit 130 may be integrally arranged or firmly fixed, upper and lower driving parts 153 that move the base plate 151 up and down, and a fixing plate 155 for fixing and supporting the upper and lower driving parts 153.

The vertical drive unit 153 can move the lower jig 150 toward the upper jig 110 or move it in a direction away from the upper jig 110.

A laminating device 100′ for a display device according to another embodiment of the disclosure may include an independently controlled heating unit 135′ installed so that the curved elastic pad part 131′ of the pad unit 130′ can self-generate, and a control device 170 for controlling the power and temperature of the independently controlled heating unit 135′ in conjunction with the control device 170, and depending on the characteristics, a local cooling device 180 that cools locally and quickly may be further included.

FIGS. 10 to 12 are cross-sectional views taken along line A-A of FIG. 9 of the pad unit according to first to third modifications of another embodiment of the disclosure, and FIG. 13 is a plan view of the pad unit according to a fourth modification of another embodiment of the disclosure.

Referring to FIGS. 10 to 12, the independently controlled heating unit 135 of the pad unit according to the first to third modifications of other embodiments of the disclosure may be in the form of a metal sheet, metal tube, or metal block.

Referring to FIG. 10, the curved elastic pad part 131′ of the pad unit 130′ may include a corner area 1311 and a central area 1312.

The corner area 1311 of the curved elastic pad part 131 may be connected to the central area 1312.

A central area 1312 may be installed between two adjacent corner areas 1311.

The corner area 1311 may be arranged to fix the edge bending area 212 (see FIG. 5) of the protective cover plate 210.

The central area 1312 may further include protruding support portions 133aa, 133ba, 133ca, and 133da protruding from the first to fourth pad side surfaces 133a, 133b, 133c, and 133d.

The protruding support parts (133aa, 133ba, 133ca, 133da) may be made of a stronger material, and are almost rectangular box-shaped, allowing the flat area 211 of the protective cover plate 210 to be more evenly arranged in relation to the central area 1312.

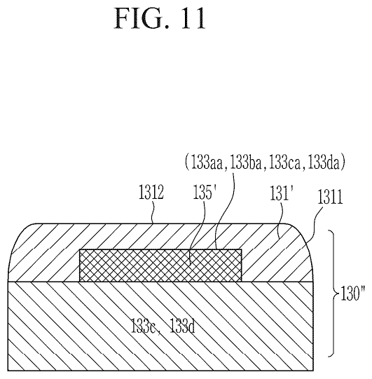

As shown in FIG. 11, in the cross-sectional view of the pad unit according to the second modification of another embodiment of the disclosure, the heating unit 135′ may be located in the central area 1312 of the curved elastic pad part 131′, and correspondingly, it may be installed in the protruding support portions 133aa, 133ba, 133ca, and 133da protruding from the first to fourth pad sides 133a, 133b, 133c, and 133d.

In case that the heating unit 135″ is installed within the protruding support parts (133aa, 133ba, 133ca, 133da) protruding from the first to fourth pad sides (133a, 133b, 133c, 133d), it can provide the effect of ironing without forming wrinkles on the display panel 230 corresponding to the flat area 211 of the above protective cover plate 210.

In the process of bonding the display panel 230 to the flat area 211 of the protective cover plate 210, the fluidity of the optical adhesive layer 220 may be improved to prevent edge bending of the protective cover plate 210, and it can be expanded into the edge bending area 212.

Also, in the process of attaching the display panel 230 to the edge bending area 212 of the protective cover plate 210, the optical adhesive layer 220 may not be heated, so the adhesiveness of the optical adhesive layer 220 can be improved.

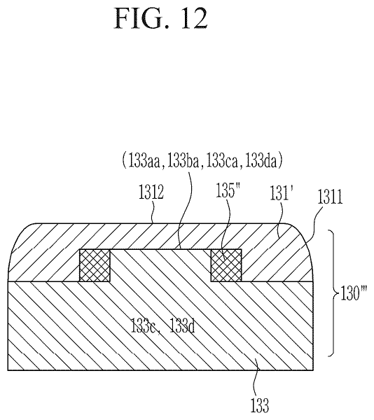

As shown in FIG. 12, in the cross-sectional view of the pad unit according to the third modification of another embodiment of the disclosure, the heating unit 135″ may be located in the corner area 1311 of the curved elastic pad part 131′, and correspondingly, it may be installed on the edge of the protruding support portions 133aa, 133ba, 133ca, and 133da protruding from the first to fourth pad sides 133a, 133b, 133c, and 133d.

In case that the heating unit 135″ is locally installed on the edge of the protruding support portions (133aa, 133ba, 133ca, 133da) protruding from the first to fourth pad sides (133a, 133b, 133c, 133d), the protective cover plate by heating the edge of the display panel 230 corresponding to the edge bending area 212 of 210, the edge portion of the display panel 230 after heating may become curved corresponding to the edge bending area 212, thereby optically line bonding of the adhesive layer 220 can be avoided and good surface sum can be achieved.

Air bubbles generated in the process of bonding the display panel 230 to the flat area 211 of the protective cover plate 210 may be trapped in the edge bending area 212 of the protective cover plate 210 and cannot readily escape, and by heating the edge of the display panel 230 corresponding to the edge bending area 212 of the protective cover plate 210, the adhesive force of the optical adhesive layer 220 may be lowered and the protective cover plate 210 of the edge of the edge bending area 212 and the display panel 230 may be slowly joined, thereby effectively reducing the possibility of air bubbles existing between the edge bending area 212 and the optical adhesive layer 220 after the bonding.

FIGS. 13A and 13B are plan views of a pad unit according to a fourth modification of another embodiment of the disclosure.

As shown in FIGS. 13A and 13B, the independently controlled heating unit 135″ may be a metal heating wire.

As shown in FIG. 13A, the independently controlled heating unit 135″ may be a first separately disposed heating unit 131′ of the pad unit 130′, and it may be a metal heating wire 135a.

The metal heating wire 135a may have a network-shaped second metal heating wire 135b in which metal heating wires 135a arranged in the x-axis direction and y-axis direction are intersected.

The metal heating wire 135a may be placed closer together or further apart in the x-axis or y-axis direction.

As shown in FIG. 13B, the independently controlled heating unit 135″ may use a third metal material in the form of a closed curve with respect to the curved elastic pad part 131′ of the pad unit 130′, and heating wires 135c may be arranged concentrically, and the closed curve shape may be elliptical, with ovals having different long axes in the x-axis direction or y-axis direction, and the curved surface of the pad unit 130′, and it may further include fourth metal heating wires 135d that are independently disposed and independently controlled with respect to the corner areas 1311 of the elastic pad part 131′.

In case that the heating unit 135″ is independently disposed using a metal heating wire or a metal heating sheet, it may be sewn to the curved elastic pad part 131′.

In case that the heating unit 135″′ is independently arranged as a metal heating wire or a metal heating sheet, it may have a small volume and may occupy a small space, enabling arrangement on the curved elastic pad part 131′ of the pad unit 130′, it can be detached from the curved elastic pad part 131′, while it does not affect the overall structural design of the pad unit 130′, and the structural design can be varied for the curved elastic pad part 131′.

FIG. 14 is a configuration diagram of a control device for a laminating device for a curved display device according to an embodiment of the disclosure.

As shown in FIG. 14, in the laminating device 100′ for a display device according to an embodiment of the disclosure, the control device 170 may include a control processing part 171, a power detection part 172, a power switching part 173, a driving part 174, a current control part 175, a temperature detection part 176, and a cooling switching part 177.

Power may be detected through the power detection part 172, and the power switching part 173 can switch the input of AC power on and off under the control of the control processing part 171.

The temperature detection part 176 may detect the temperature generated by each of the first to fourth metal heating wires 135a, 135b, 135c, and 135d of the heating unit 135″ and may input a temperature detection signal to the control processor 171.

The driving part 174 may control the current control part 175 according to the control signal authorized from the control processing part 171, and may authorize the control signal authorized from the control processing part 171 as a drive control signal to the current control part 175 by converting it into a voltage that may be desirable for the operation of the current control part 175.

The current control part 175 can be operated according to the control signal applied from the driving part 174, and can individually control the current applied to the independent control heating unit 135″′ consisting of the first to fourth metal heating wires (135a, 135b, 135c, 135d).

The control processing part 171 may be implemented as a microprocessor and may control the overall operation of the heating unit 135″ of the pad unit 130′ according to a built-in program, and may use voltage and phase detection signals applied from the power detection unit 172 that may be converted into a digital signal by the built-in analog/digital converter to determine the voltage and phase of the power supply, and the temperature detection signal applied from the temperature detection part 176 may be converted into a digital signal by the built-in analog/digital converter. By converting, the temperature may be determined and a control signal may be output to the driving part 174 to independently control the edge bending area 1311 and the flat area 1312 of the curved elastic pad unit 131′ of the pad unit 130′, and the current of the disposed independent heating unit 135″′ may be adjusted.

The control processing part 171 may control to maintain the set temperature by independently detecting the temperature signals corresponding to the temperatures of each of the first to fourth metal heating wires 135a, 135b, 135c, and 135d from the independently controlled heating unit 135″′ composed of the first to fourth metal heating wires 135a, 135b, 135c, and 135d by the temperature detection part 176, and driving the current control part 175 to maintain the set temperature while confirming the temperatures of each of the first to fourth metal heating wires 135a, 135b, 135c, and 135d.

The current control part 175 can be implemented as a silicon controlled rectifier (hereafter, referred to as ‘SCR’), which includes two first SCR1 s 175a installed at both ends of each of the first to fourth metal heating wires 135a, 135b, 135c, and 135d, and a second SCR2 175b.

The first SCR1 175a and the second SCR2 175b may receive a control signal applied from the control processing part 171 through the driving part 174 to the gate terminal, and operate the first SCR1 175a and the first SCR2 175b according to the control signal input to the corresponding gate terminal, so the amount of current supplied to each of the fourth metal heating wires 135a, 135b, 135c, and 135d is adjusted.

The temperature detection part 176 may be composed of first and second temperature detection parts 176a and 176b. The first temperature detection part 176a may detect the temperature of the first metal heating wire 135a that receives current through the first SCR1 175a and may input it to the control processing part 171. The second temperature detection part 176b may detect the temperature of the second metal heating wire 135b that receives current through the second SCR2 175b and may input it to the control processing part 171.

The first and second temperature detection parts 176a and 176b may include a resistor that determines the current value of the temperature signal, a Zener diode that limits the voltage applied to the control processing part 171 so that it does not exceed a predetermined direct current value, and an applied temperature, and a condenser can be connected to smooth the sinusoidal waveform of the signal.

In case that the temperature detection part 176 detects the temperature and inputs it to the control processing part 171, the cooling switching unit 177 may operate the cooling devices 180a and 180b under the control of the control processing part 171 to cool the first and second metal heating wires 135a and 135b.

A laminating method for a curved display device according to an embodiment of the disclosure will be described in detail with reference to FIG. 15.

FIG. 15 is a schematic flowchart showing a control method of a laminating device for a display device according to another embodiment of the disclosure.

As shown in FIG. 15, the laminating method for a curved display device according to another embodiment of the disclosure involves bending the middle planar area 211 and the edges around the planar area 211 using the upper jig 110, and a step S10 of providing a protective cover plate 210 including an area 212.

A step S20 of providing a pad unit 130 disposed below the upper jig 110 using the lower jig 150 is also provided.

A step S30 of providing a display panel 230 having an optical adhesive layer 220 on a pad unit 130 disposed below the upper jig 110 is further provided.

The pad unit disposed on the protective cover plate 210 below the upper jig 110 and the lower jig 150 by moving the upper jig 110 or the lower jig 150 in directions perpendicular to each other, in a step S40 of bonding the display panel 230 on the pad unit 130 via an optical adhesive layer 220.

The step S40 of bonding the protective cover plate 210 and the display panel 230 via an optical adhesive layer 220 can further include the step S50 of heating the central area of the display panel 230 corresponding to the flat area 211 of the protective cover plate 210, and the step S60 of locally increasing the fluidity of the optical adhesive layer 220 placed on the central area of the display panel 230 using the heat transmitted through the step S50 of heating the central area of the display panel 230 to form a curved area.

In the step S40 of bonding the protective cover plate 210 and the display panel 230 through the optical adhesive layer 220, the display panel corresponding to the edge bending area 212 of the protective cover plate 210 forming a curved area by heating the edge area of the display panel 230 in step S60, and heating the edge area of the display panel 230 to form an optical adhesive layer 220 disposed on the edge area of the display panel 230 heating to slow down the adhesion speed S70, and an edge area of the display panel 230 compared to the bonding of the flat area 211 of the protective cover plate 210 and the central area of the display panel 230 and slowing down the bonding of the edge area of the display panel 230, and gradually releasing the air bubbles trapped in the edge bending area 212 by pressing the edge area of the display panel 230 and the edge area of the display panel 230, in a step S80 of removing unexpected defects, such as complete removal, may be included.

Therefore, the edge area of the display panel 230 that is joined to at least a portion of the edge bending area 212 of the protective cover plate 210 may avoid line contact and may make surface contact, so that the optical adhesive layer 220 is well filled on the inner surface, and this can effectively reduce the possibility of air bubbles existing between the optical adhesive layer 220 and the edge bending area 212 after bonding.

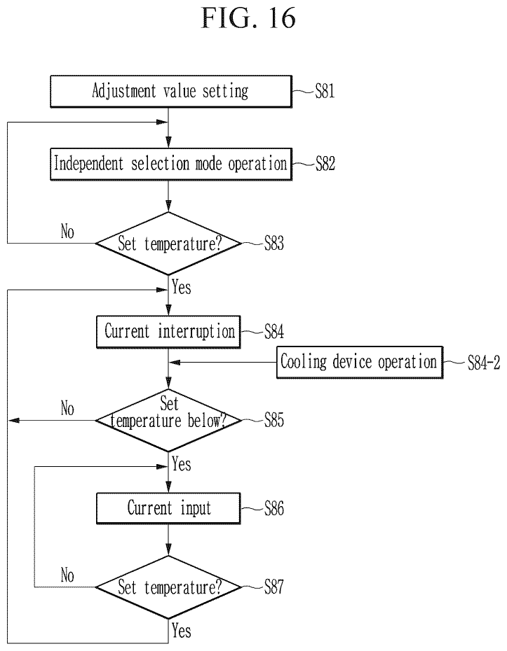

A laminating method for a curved display device according to an embodiment of the disclosure will be described in detail with reference to FIG. 16.

FIG. 16 is a schematic flowchart showing the expected defect control method of FIG. 15.

As described in FIG. 16, a method for laminating a curved display device according to another embodiment of the disclosure includes moving the upper jig 110 or the lower jig 150 in a direction perpendicular to each other, and in case joining the protective cover plate 210 under the upper jig 110 and the display panel 230 placed on the lower jig 150, it includes a step S80 of controlling the expected defects due to the line contact of the optical adhesive layer 220.

In case bonding the protective cover plate 210 and the display panel 230, the step S80 for controlling expected defects due to line contact of the optical adhesive layer 220 includes the protective cover plate 210, the adjusting the bonding time, temperature, bonding strength, etc. of the protective cover plate 210 and the display panel 230 in consideration of the optical adhesive layer 220 and the curved shape, material, and physical properties of the display panel 230, a step of setting the value S81, and the protective cover plate, it may include a step S82 of driving an independent selection mode for each of the first to fourth metal heating wires 135a, 135b, 135c, and 135d installed in the flat area 211 and the edge bending area 212 of 210.

It can include a step S83 of determining whether each of the first to fourth metal heating wires 135a, 135b, 135c, and 135d has reached the set temperature corresponding to the flat area 211 and the edge bending area 212 of the protective cover plate 210.

If it is determined that the set temperature has not been reached corresponding to the flat area 211 and the edge bending area 212 of the protective cover plate 210, the first to fourth metal heating wires 135a, 135b, 135c, and 135d are independently selected in step S82 and may include a change step for each.

If it is determined that the flat area 211 and the edge bending area 212 of the above-mentioned protective cover plate 210 have reached the set temperature, it may include a step S84 of independently cutting off the current for each of the first to fourth metal heating wires 135a, 135b, 135c, and 135d.

If it is determined that the temperature exceeds the set temperature corresponding to the flat area 211 and the edge bending area 212 of the protective cover plate 210, the temperature can be instantaneously controlled using the cooling device 180 (S84-2).

If it is determined that the temperature is below the set temperature corresponding to the flat area 211 and the edge bending area 212 of the protective cover plate 210 (S85), the first to fourth metal heating wires 135a, 135b, 135c, and 135d are again heated, and it may include a step S86 of applying current independently to each.

In case that it is determined that the set temperature corresponding to the flat area 211 and the edge bending area 212 of the protective cover plate 210 has been reached (S87), the current can be blocked again.

The step S82 of driving an independent selection mode for each of the first to fourth metal heating wires 135a, 135b, 135c, and 135d may control the current by outputting a driving control signal from the control processing part 171 to the driving part 174. Each SCR of the unit 175 may supply maximum current to the first to fourth metal heating wires 135a, 135b, 135c, and 135d.

While supplying current to the first to fourth metal heating wires 135a, 135b, 135c, and 135d, the control processing part 171 may be installed on the first to fourth metal heating wires 135a, 135b, 135c, and 135d. By detecting the local temperature corresponding to the flat area 211 and the edge bending area 212 of the protective cover plate 210 through the temperature detection part 176, it may be possible to check whether the set temperature has been reached for each area.

If the set temperature is not reached, the operation may be repeated by returning to step S82 described above, and if the set temperature is reached, a control signal may be applied to the driving part 174 to control the power supplied by the SCR of the current control part 175, the current may be blocked to prevent the temperature of each of the first to fourth metal heating wires 135a, 135b, 135c, and 135d from rising above the set temperature (S84).

The control processing part 171 may check whether the temperature is falling below the set temperature through the temperature detection part 176 while selectively blocking the supply current of each of the first to fourth metal heating wires 135a, 135b, 135c, and 135d (S85). If the temperature does not fall below the set temperature, it may return to step S84 and may maintain the current blocking state. If the temperature falls below the set temperature, it may apply a control signal to the driving part 174 and may supply current through the SCR of the current control part 175, supplying an appropriate current that can reach the set temperature, thereby raising the temperature of the heating wire (S86).

While supplying current to the heating wire in this way, the control processing part 171 may check whether the temperature of the first to fourth metal heating wires 135a, 135b, 135c, and 135d reach the set temperature through the temperature detection part 176 (S87). If the set temperature has not been reached, it may return to step S86 to continue supplying current to the first to fourth metal heating wires (135a, 135b, 135c, 135d), and if the set temperature has been reached, it may return to step S84, and the current supplied to the first to fourth metal heating wires 135a, 135b, 135c, and 135d is blocked by the current control part 175.

In case that the carrier film 300 is provided on the curved elastic pad part 131 of the above pad unit 130, the heating unit 135 inside the curved elastic pad part 131 may be heated along the curved surface of the curved elastic pad part 131, causing the display panel 230 provided by the carrier film 300 to elastically deform, forming an edge that follows the curved surface, which allows it to naturally and tightly attach, avoiding direct contact with the edge bending area 212 of the protective cover plate 210.

Since a curved surface is formed on the display panel 230 before laminating between the protective cover plate 210 and the display panel 230, the surface of the display panel 230 may be excessively compressed and the protective cover plate 210 and the display panel 230 can be prevented from being damaged due to differences in curvature during laminating, and may also be selective for the optical adhesive layer 220 between the protective cover plate 210 and the display panel 230, and by controlling the temperature, the optical adhesive layer 220 may be prevented from peeling off or bubbles from being generated between the protective cover plate 210 and the display panel 230, so the overall production rate can be increased, and the laminating speed can be accelerated.

Since the optical adhesive layer 220 itself may be made of acrylic with high light transmittance of about 95% or more, the optical adhesive layer 220 may control fluidity and adhesion by taking into account that the optical adhesive layer 220 has better viscosity at room temperature than at high temperature, so it can be cured to correspond to the shape of the display panel 230 and the protective cover plate 210 and to prevent bubbles or line contact defects from occurring.

After the protective cover plate 210 and the display panel 230 are completely bonded, the optical adhesive layer 220 may be hardened.

In the process of bonding the display panel 230 and the protective cover plate 210, wrinkles or bubbles may appear in the optical adhesive layer 220 corresponding to the inner surface of the edge bending area 212, but the display panel, by applying tension to the edge of the display panel 230 to bend the edge of the display panel 230 toward the pad unit 130, it may be ensured that the shape of the display panel 230 matches the shape of the protective cover plate 210.

The optical adhesive layer 220 corresponding to the middle part of the flexible panel 230 can first contact and bond with the middle flat area 211 of the protective cover plate 210, and release the edge part of the display panel 230, allowing the film to be pulled and terminated.

The edge portion of the display panel 230 may have elastic recovery properties.

The edge of the display panel 230 may operate under its own elastic restoring force, driving the corresponding optical adhesive layer 220 to closely approach the edge bending area 212 of the protective cover plate 210, and contacting the edge bending area 212 of the protective cover plate 210.

The optical adhesive layer 220 corresponding to the middle part of the flexible panel 230 may be contacted with the middle plane area 211 of the protective cover plate 210, and air bubbles generated during the bonding process may be removed from the area where the edge portion is not bonded, so they can be discharged, and the possibility of air bubbles occurring between the optical adhesive layer 220 and the mid-plane area 211 of the protective cover plate 210 may be reduced.

In case that the heating unit 135 heats the optical adhesive layer 220, the display panel 230 may simultaneously be heated and the temperature of the display panel 230 may also increase.

After the temperature rises, the edge portion of the display panel 230 for joining the edge bending area 212 may become softer and the rigidity may decrease, so that the elastic recovery force of the edge portion of the display panel 230 may decrease.

Therefore, after the carrier film supply 120 releases the display panel 230, the supply speed of the edge portion of the display panel 230 may be slowed to first contact the area adjacent to the middle plane area 211 and edge bending, the regions 212 may be brought into contact so that all air bubbles can be discharged between the optical adhesive layer 220 and the edge bending region 212.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A laminating device for a curved display device, bonding a display panel to a protective cover plate including a flat area and an edge bending area around the flat area with an optical adhesive layer, the laminating device for the curved display device comprising:
a pad portion with the display panel provided on top;
a lower jig that supports the pad portion and is configured to move up and down perpendicular to an upper jig; and
an independently controlled heating unit installed on the pad portion, that selectively or independently controls a temperature of the optical adhesive layer on at least a portion of the protective cover plate during bonding of the protective cover plate and the display panel to eliminate unpredictability in edge bending areas of the protective cover plate.

2. The laminating device for the curved display device of claim 1, further comprising:
an upper jig including:
a fixing part that fixes the protective cover plate by vacuum suction; and
a moving part that moves the protective cover plate fixed by the fixing part,
wherein the lower jig includes:
a base plate supporting a support body of the pad portion, and
a vertical driving part that vertically drives the pad portion.

3. The laminating device for the curved display device of claim 1, wherein
the pad portion includes a curved elastic pad part on which the display panel is disposed and whose upper surface changes to correspond to the curved shape of the protective cover plate in case that the upper jig or the lower jig moves in a vertical direction, and
a support body configured to be detachable from the curved elastic pad part,
wherein the independently controlled heating member is selectively installed with respect to the curved elastic pad part.

4. The laminating device for the curved display device of claim 3, wherein
a carrier film supply unit that supplies a carrier film to which the display panel is attached is installed offset with respect to the pad portion.

5. The laminating device for the curved display device of claim 1, comprising
a control device that independently controls power and temperature of the independently controlled heating member so that a curved elastic pad part of the pad portion can self-generate.

6. The laminating device for the curved display device of claim 5, comprising:
a temperature sensor installed for each of the independently controlled heating members, and a control device that communicates with the temperature sensor to independently control power on/off and temperature of the independently controlled heating member.

7. The laminating device for the curved display device of claim 6, further comprising
a cooling device that locally and quickly cools the independently controlled heating member in conjunction with the control device.

8. The laminating device for the curved display device of claim 6, wherein
the independently controlled heating member is a laminating device for the curved display device, and the independently controlled heating member is at least one of a metal sheet, a metal tube, a metal block, and a metal wire.

9. The laminating device for the curved display device of claim 8, wherein
the independently controlled heating member is disposed in a central area of the curved elastic pad part corresponding to the flat area of the protective cover substrate, and the central area of the curved elastic pad part is surrounded by a protruding support portion protruding upward from a support body.

10. The laminating device for the curved display device of claim 8, wherein
the independently controlled heating member is disposed in a corner area of the curved elastic pad part corresponding to the edge bending area of the protective cover substrate, and the corner area is a curved display formed outside a protruding support portion protruding upward from a support body.

11. The laminating device for the curved display device of claim 1, wherein
the optical adhesive layer is made of an acrylic optical adhesive, has low high-temperature adhesive strength compared to room-temperature adhesive strength, and modulus and cohesion decrease as the temperature increases.

12. The laminating device for the curved display device of claim 8, wherein
the independently controlled heating member includes a first metal heating wire that is independently and discretely disposed with respect to the curved elastic pad part, and a second metal heating wire in the form of a mesh that intersects in an x-axis direction and a y-axis direction,
the independently controlled heating member has controllable spacing in the x-axis direction and y-axis direction and can be sewn to the curved elastic pad part, and
the independently controlled heating member includes a third metal heating wire in the form of a closed curve that is independently and discretely disposed with respect to the curved elastic pad part, and a fourth metal heating wire that is independently disposed and independently controlled with respect to a corner area of the curved elastic pad part.

13. A laminating method for a curved display device, comprising:
providing a protective cover plate including a middle flat area and an edge bending area around the flat area using an upper jig;
providing a pad portion disposed below the upper jig using a lower jig;
providing a display panel having an optical adhesive layer on the pad portion;
moving the upper jig or the lower jig in directions perpendicular to each other to bond the protective cover plate below the upper jig and the display panel on the pad portion disposed on the lower jig through the optical adhesive layer; and
eliminating unpredictability occurring in an edge bending area of the protective cover plate by selectively or independently controlling a temperature of the optical adhesive layer for at least a portion of the protective cover plate.

14. The laminating method for the curved display device of claim 13, further comprising:
removing wrinkles by heating a central area of the display panel corresponding to a flat area of the protective cover plate;
increasing fluidity by indirectly heating the optical adhesive layer disposed on the central area of the display panel.

15. The laminating method for the curved display device of claim 13, comprising
forming a curved area by heating an edge area of the display panel corresponding to an edge bending area of the protective cover plate.

16. The laminating method for the curved display device of claim 13, comprising
heating the edge area of the display panel to lower adhesive strength compared to room temperature by heating the optical adhesive layer disposed on the edge area of the display panel to a high temperature above room temperature, and
removing air bubbles through the edge area of the corresponding display panel.

17. The laminating method for the curved display device of claim 13, wherein
the temperature of the optical adhesive layer on the display panel is selectively or independently controlled for at least a portion of said protective cover plate by moving the upper jig or the lower jig in a direction perpendicular to each other while joining the curved protective cover plate below the upper jig and the display panel disposed on the lower jig to eliminate unpredictability in the edge bending region of the protective cover plate,
the temperature of the optical adhesive layer is controlled through an independently controllable heating member included in the pad portion on which the display panel is disposed, and the independently controllable heating member is embedded in an entire area or partial area of the pad portion, and
the independently controlled heating member is a metal sheet, metal tube, or metal block selectively disposed in a central area or edge area of the pad portion, a mesh-shaped metal heating wire intersecting an x-axis direction and a y-axis direction, or has a discrete closed curve shaped.

18. The laminating method for the curved display device of claim 17, wherein
a plurality of independently controlled heating members are disposed separately, each is controlled on and off according to a temperature measurement value measured by a temperature sensor disposed on each, and the temperature is variable.

19. A curved display device, comprising:
a display panel, and
a protective cover plate including a flat area and an edge bending area around the flat area with an optical adhesive layer, wherein
the display panel and the protective cover plate are bonded to each other, and
unpredictability in the edge bending area is eliminated by selectively or independently controlling a temperature of the optical adhesive layer for at least a portion of the protective cover plate while bonding the protective cover plate and the display panel.

20. The curved display device of claim 19, wherein
a predicted amount is a bonding defect that occurs in case that the optical adhesive layer makes line contact with the edge bending area of the protective cover plate, and
the bonding defect is caused by chafing, bending, or stress accumulation of an optical adhesive forming the optical adhesive layer, through at least one of buckling, film delamination, and bubbling.
